(19) United States
(12) Patent Application Publication
(10) Pub. No.: US 2011/0292579 A1
(43) Pub. Date: Dec. 1, 2011

(54) KEYBOARD MODULE AND ELECTRONIC APPARATUS

(75) Inventor: Yuichi KOGA, Hachioji-shi (JP)

(73) Assignee: KABUSHIKI KAISHA TOSHIBA, Tokyo (JP)

(21) Appl. No.: 13/105,741

(22) Filed: May 11, 2011

(30) Foreign Application Priority Data
May 26, 2010 (JP) 2010-120883

(51) Int. Cl. H05K 7/00; H03K 17/94

(52) U.S. Cl. 361/679.01; 341/22

(57) ABSTRACT

According to one embodiment, an electronic apparatus includes a casing, a keyboard unit and a spacer. The casing includes a first face exposed to an outside region, a second face opposed to the first face and a plurality of hole sections penetrating from the first face to the second face. The keyboard unit includes a keyboard base arranged inside the casing and a plurality of key caps. The key caps are movably supported by the keyboard base at positions corresponding to the hole sections, and are exposed to the outside region of the casing. The spacer is located between the casing and the keyboard base and includes an insertion section in which the key caps are inserted. At least part of the key caps are located inside the hole sections.

### CROSS-REFERENCE TO RELATED APPLICATIONS

This application is based upon and claims the benefit of priority from Japanese Patent Application No. 2010-120883, filed May 26, 2010; the entire contents of which are incorporated herein by reference.

### FIELD

Embodiments described herein relate generally to a keyboard module and an electronic apparatus.

### BACKGROUND

An electronic apparatus such as a personal computer comprises a keyboard for input. In the case of a notebook-sized portable personal computer, a keyboard is provided on the main body of the portable computer.

The keyboard has a keyboard base and a plurality of key caps. The keyboard caps are supported in such a manner that they can be depressed closer to the keyboard base by a type mechanism. Based on type mechanisms employed, keyboards include membrane type keyboards, mechanical keyboards, pantograph keyboards, etc.

In a general type of keyboard, a casing has a wide opening, and a plurality of key caps are received in the wide opening. In contrast, in a so-called isolation keyboard, a casing has a plurality of hole sections, and a plurality of key caps are provided in the hole sections in an exposed state. In other words, a frame is located between the adjacent key caps. Therefore, the key caps are arranged independently of one another.

Desirably, portable electronic apparatuses such as portable computers should be thin and light in weight. The casings of the electronic apparatuses are formed to be thin and are partly formed of a light metallic material such as a magnesium alloy.

To make user's typing comfortable, the key depression distance of a keyboard has to be a certain distance. Therefore, a certain distance has to be provided between the keyboard base of the keyboard and the key caps.

In some types of keyboard, a keyboard base is fixed to the rear surface of a casing in which a plurality of hole sections are formed. In these types of keyboard, the key caps may be located higher than the surface of the casing if the casing is thin. In other words, a gap is provided between the key caps and the casing.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a portable computer according to the first embodiment;

FIG. 2 is an exemplary plan view showing the main unit of the first embodiment;

FIG. 3 is an exemplary partly-exploded perspective view of the main unit of the first embodiment;

FIG. 4 is an exemplary cross sectional view taken along line F4-F4 in FIG. 2 and showing part of the main unit;

FIG. 5 is an exemplary partly-exploded perspective view of the main unit of a portable computer according to the second embodiment;

FIG. 6 is an exemplary partly-exploded perspective view of the main unit of a portable computer according to the third embodiment; and

FIG. 7 is an exemplary sectional view showing part of the keyboard module of the third embodiment.

### DETAILED DESCRIPTION

Various embodiments will be described hereinafter with reference to the accompanying drawings.

In general, according to one embodiment, an electronic apparatus includes a casing, a keyboard unit and a spacer. The casing includes a first face exposed to an outside region, a second face opposed to the first face and a plurality of hole sections penetrating from the first face to the second face. The keyboard unit includes a keyboard base arranged inside the casing and a plurality of key caps. The key caps are movably supported by the keyboard base at positions corresponding to the hole sections, and are exposed to the outside region of the casing. The spacer is located between the casing and the keyboard base and includes an insertion section in which the key caps are inserted. At least part of the key caps are located inside the hole sections.

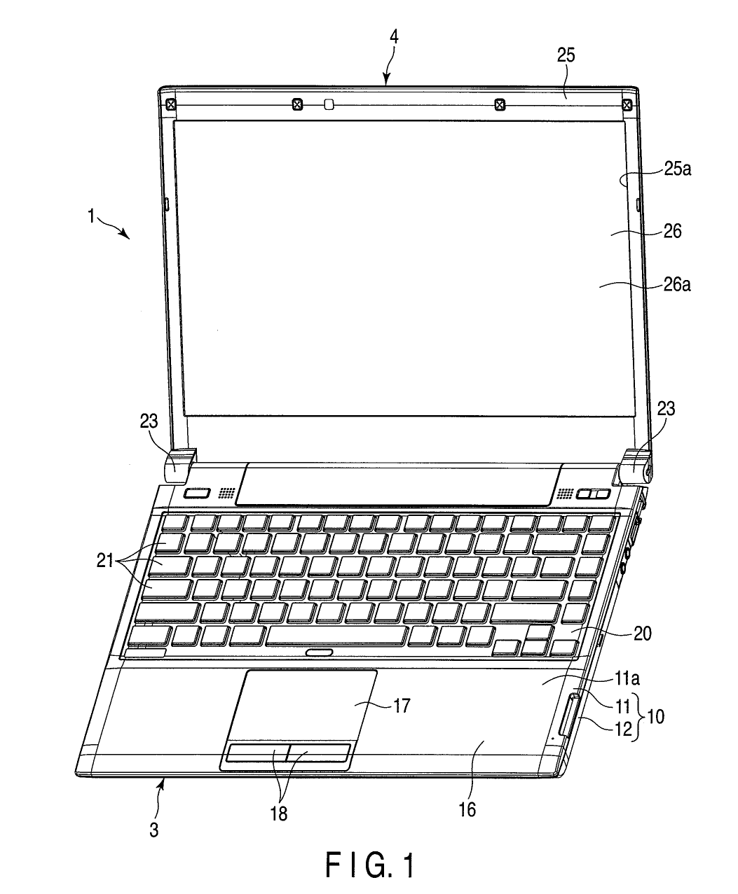

A description will be given of the first embodiment with reference to FIGS. 1 through 4. In this specification, the side nearest the user is defined as the front; that furthest from the user, the rear; that to the left of the user, the left; that to the right of the user, the right; that facing upward relative to the user, up; and that facing downward relative to the user, down.

FIG. 1 is a perspective view of a portable computer 1. The portable computer 1 is an example of an electronic apparatus. As shown in FIG. 1, the portable computer 1 comprises a main body unit 3 and a display unit 4.

The main unit 3 comprises a flat box-like casing 10. The casing 10 includes an upper cover 11 and a lower cover 12. The upper cover 11 is an example of a cover member. The upper cover 11 is attached to the lower cover 12 in such a manner as to cover the lower cover 12. The upper cover 11 is formed of a magnesium alloy, for example. Needless to say, the upper cover 11 may be formed of another kind of material, such as an aluminum alloy or a synthetic resin.

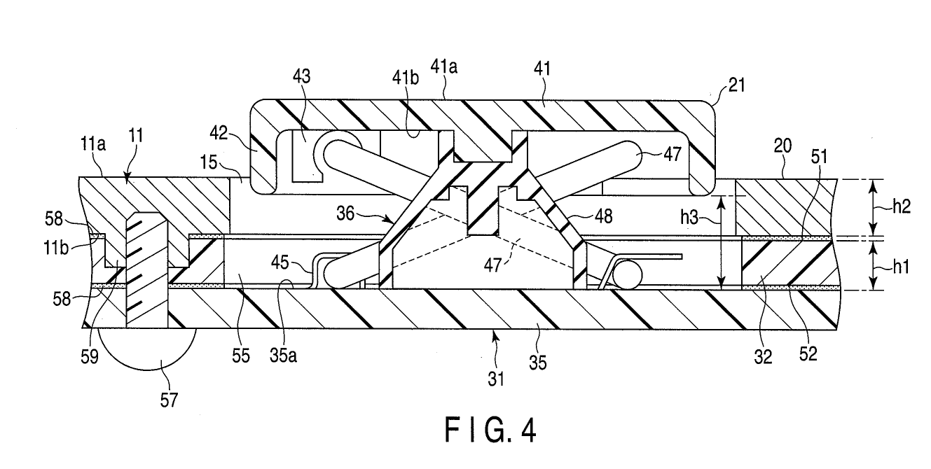

The upper cover 11 includes an outer face 11a and an inner face 11b (shown in FIG. 4). The outer face 11a is exposed to the outside of the portable computer 1. The outer face 11a is an example of a first face of the casing, and is also an example of a first face of the cover member. The inner face 11b is the opposite side of the outer face 11a. The inner face 11b is an example of a second face of the casing, and is also an example of a second face of the cover member.

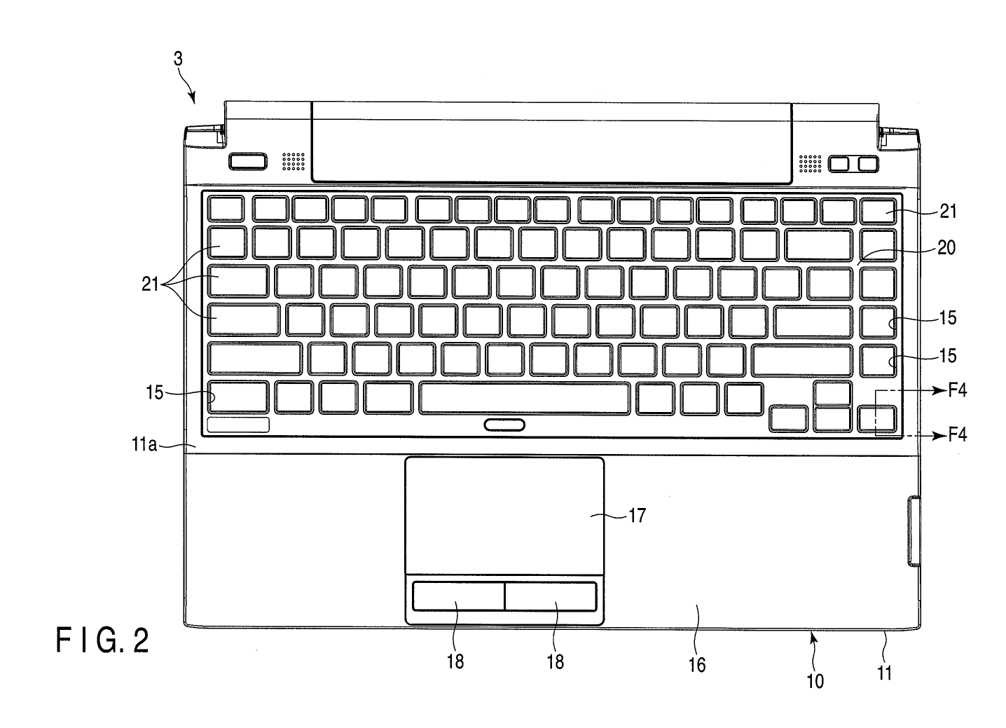

FIG. 2 is a plan view showing how the main unit 3 looks like when viewed from above. As shown in FIG. 2, a plurality of hole sections 15, a palm rest 16, a touch pad 17 and a pair of buttons 18 are provided for the outer face 11a of the upper cover 11.

The hole sections 15 are openings penetrating from the outer face 11a of the upper cover 11 to the inner face 11b thereof. Since the hole sections 15 are provided in the upper cover 11, the upper cover 11 forms a lattice-like frame 20.

A plurality of key caps 21 are provided in the hole sections 15 and exposed to the outside of the casing 10. Each key cap 21 has a size that can be fitted in the corresponding one of the hole sections 15. As shown in FIG. 2, the frame 20 is located between the adjacent key caps 21, and the key caps 21 are therefore arranged independently of one another. A plurality of key caps 21 may be located in a single hole section 15 in an exposed state.

The palm rest 16 is located on the front side of the hole sections 15. The touch pad 17 and the buttons 18 are arranged side by side in the central portion of the palm rest 16. The touch pad 17 is used as a pointing device. The buttons 18 are used for click operations.

As shown in FIG. 1, the display unit 4 is coupled to the rear end of the main unit 3 by means of a pair of hinges 23. The hinges 23 are provided at the rear end of the main unit 3.

The display unit 4 is rotatable between a closed position and an open position, with the hinges as a fulcrum. At the closed position, the display unit 4 is laid on the main unit 3. At the open position, the display unit 4 is raised from the rear end of the main unit 3.

The display unit 4 comprises a flat box-like display casing 25 and a display module 26. The display module 26 is a liquid crystal display, for example, and is contained in the display casing 25.

The display casing 25 has a display opening 25a formed in the front face thereof. The display opening 25a permits the screen 26a of the display module 26 to be exposed to the outside of the display unit 4.

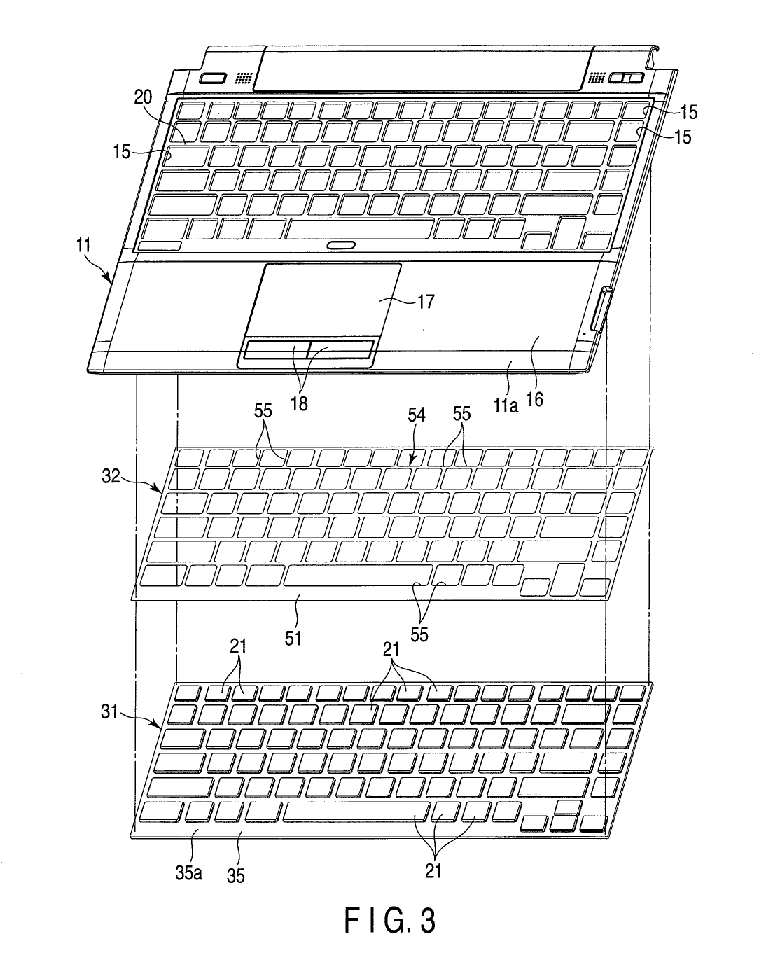

FIG. 3 is a partly-exploded perspective view of the main unit 3 of the first embodiment. As shown in FIG. 3, a keyboard unit 31 and a spacer 32 are contained inside the casing 10. In addition to the keyboard unit 31 and the spacer 32, a circuit board, a storage, and other electronic components are contained inside the casing 10.

FIG. 4 is a cross sectional view taken along line F4-F4 in FIG. 2 and showing part of the main unit 3. As shown in FIG. 4, the keyboard unit 31 comprises a plurality of key caps (described above), a keyboard base 35, and a plurality of type mechanisms 36. The keyboard unit 31 is a pantograph type keyboard.

The key caps 21 are supported on the keyboard base 35 at positions corresponding to the hole sections 15 of the upper cover 11. The hole sections 15 and the key caps 21 are arranged at the positions determined by a predetermined rule.

Each key cap 21 includes a key top 41, a peripheral portion 42 and a first coupling portion 43. The key top 41 has a size permitting the user to depress it. A character and a symbol representing the function of the key cap 21 are shown on the upper face 41a of the key top 41. The character and symbol are marked on the upper face 41a of the key top 41 by printing or engraving.

The peripheral portion 43 extends from the periphery of the key top 41 toward the keyboard base 35. The first coupling portion 43 is provided on the lower face 41b of the key top 41. The type mechanism 36 is coupled to the first coupling portion 43.

The keyboard base 35 is formed like a flat plate and is arranged inside the casing 10. The keyboard base 35 is electrically connected to a circuit board such as a motherboard. A second coupling portion 45 is provided on the upper face 35a of the keyboard base 35. The type mechanism 36 is coupled to the second coupling portion 45.

A plurality of switches are provided inside the keyboard base 35. The switches are located at positions corresponding to the key caps 21. The switches are operated when the key caps 21 are depressed.

Each type mechanism 36 couples the corresponding one of the key caps 21 to the keyboard base 35. The type mechanism 36 movably supports the key cap 21 in such a manner that the key cap 21 is movable between the standby position shown in FIG. 4 and a depressed position taken when the key cap 21 is depressed.

The type mechanism 36 includes a pair of link levers 47 and a rubber spring 48. The link levers 47 are made to intersect with each other in the shape of “X” and pivotally coupled at the intersection. The link levers 47 are coupled to the first coupling portion 43 and the second coupling portion 45.

The rubber spring 48 is located between the key cap 21 and the keyboard base 35. When the key cap 21 is depressed, the rubber spring 48 serves to move the key cap 21 upward. When no external force is applied to the key cap 21, the key cap 21 is located at the standby position shown in FIG. 4.

As shown in FIG. 4, when the key cap 21 is at the standby position, it is partly located in the hole section 15 of the upper cover 11. To be more specific, part of the peripheral portion 42 of the key cap 21 is located inside the hole section 15.

When one of the key caps 21 is depressed, the corresponding switch provided in the keyboard base 35 is operated. As a result, the depression of the key cap 21 is electrically detected, and the electric signal corresponding to the depressed key cap 21 is output.

The spacer 32 is located between the upper cover 11 and the keyboard base 35. The spacer 32 is formed of polyimide, namely, a material having a specific gravity less than that of a magnesium alloy. The spacer 32 is not limited to polyimide but may be any of a variety of materials, such another kind of synthetic resin or glass fiber.

The spacer 32 has a first contact face 51 and a second contact face 52. The second contact face 52 is the opposite side of the first contact face 51. The first contact face 51 is in plane contact with the inner face 11b of the cover member 11. The second contact face 52 is in plane contact with the upper face 35a of the keyboard base 35.

As shown in FIG. 3, the spacer 32 comprises an insertion section 54. The insertion section 54 includes a plurality of insertion holes 55. The insertion holes 55 are located at positions corresponding to the key caps 21 and the hole sections 15 of the upper cover 11. As shown in FIG. 4, the insertion holes 55 penetrate from the first contact face 51 to the second contact face 52.

The insertion holes 55 are configured to receive the corresponding key caps 21. The insertion holes 55 are wider than the hole sections 15 of the upper cover 11. The corresponding ones of the key caps 21 and type mechanisms 36 are inserted in each of the insertion holes 55. In other words, a plurality of key caps 21 and a plurality of type mechanisms 36 are inserted in the insertion section 54.

The spacer 32 is secured to both the upper cover 11 and the keyboard base 35 by use of a plurality of fixing members (such as screws) and a waterproof adhesive agent 58. To be more specific, each of the first contact face 51 and the second contact face 52 is coated with the adhesive agent 58. The first contact face 51 having the adhesive agent 58 coated thereon is kept in plane contact with the inner face 11b of the upper cover 11. As a result, the first contact face 51 is secured to the upper cover 11. Likewise, the second contact face 52 having the adhesive agent 58 coated thereon is kept in plane contact with the upper face 35a of the keyboard base 35. As a result, the second contact face 52 is secured to the keyboard base 35.

The upper cover 11 comprises a plurality of boss sections 59 formed on the inner face 11b thereof. The boss sections 59 are located at positions corresponding to the four corners and center of the spacer 32.

As shown in FIG. 4, a plurality of fixing members 57 extend through the keyboard base 35 and the spacer 32 and inserted into the boss sections 59. With this structure, the fixing members 57 serve to secure the keyboard base 35 and the spacer 32 to the upper cover 11.

As described above, the spacer 32 is sandwiched between the upper cover 11 and the keyboard base 35. With this structure, the keyboard base 35 is away from the upper cover 11 by the distance corresponding to the thickness of the spacer 32.

To be more specific, the thickness h1 of the spacer 32 is 0.4 mm, for example. The thickness h2 of the upper cover 11 is 0.5 mm, for example, at positions where the upper cover 11 is opposed to the keyboard base 35. The distance h3 between the lower end of the key cap 21 located at the standby position and the upper face 35a of the keyboard base 35 is 0.8 mm, for example.

The distance between the upper face 35a of the keyboard base 35 and the outer face 11a of the upper cover 11 is a total sum of h1, h2 and the thickness of the adhesive agent 58, and is 0.9 mm or more. Since h3 is 0.8 mm, the key cap 21 at the standby position is inserted into the hole section 15 by 0.1 mm or more. In other words, part of the key cap 21 is located inside the hole section 15 of the upper cover 11.

Let us assume that the keyboard base 35 is secured directly to the upper cover 11 without the spacer 32 being used. In this case, a gap of approximately 0.3 mm is created between the lower end of the key cap 21 located at the standby position and the outer face 11a of the upper cover 11. In the portable computer 1 of the present embodiment, the spacer 32 is located between the upper cover 11 and the keyboard base 35. With this structure, no gap is created between the key cap 21 and the upper cover 11.

The portable computer 1 of the above structure is advantageous in that no gap is created between the key caps 21 and the upper cover 11. In other words, the key caps 21 are not located higher than the face of the casing 10. Owing to this feature, the internal structure (such as the type mechanisms 36) of the keyboard unit 31 is not easy to visually perceive. In addition, the key caps cannot be easily removed because a nail or other finger portions cannot be inserted into a gap.

The spacer 32 is formed of a material having a specific gravity less than that of the upper cover 11. In comparison with the case where the upper cover 11 is thicker, the weight of the portable computer 1 can be light in weight.

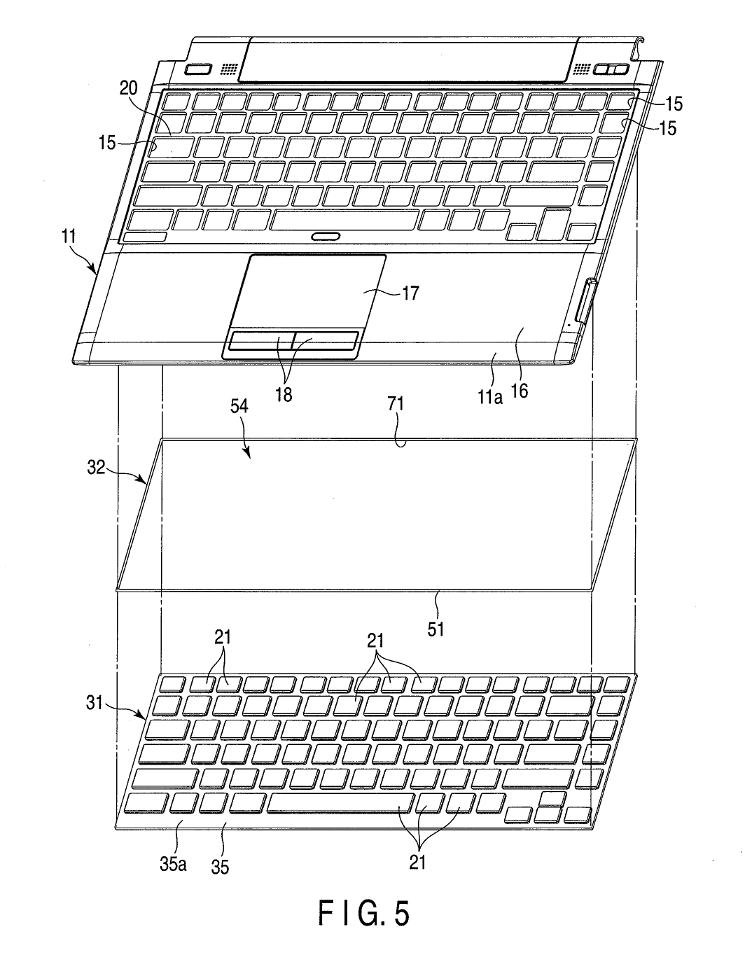

A description will now be given of a second embodiment with reference to FIG. 5. In the description below, the same reference numerals will be used to denote structural elements having the same functions as the structural elements of the portable computer 1 of the first embodiment, and a repetitive description of such structural elements will be omitted.

FIG. 5 is a partly-exploded perspective view the main unit 3 of a portable computer 1 according to the second embodiment. As shown in FIG. 5, the spacer 32 used in the second embodiment comprises an insertion opening 71. The insertion opening 71 has a size that permits all key caps 21 to pass through it. The insertion opening 71 is included in the insertion section 54.

The spacer 32 is sandwiched between an upper cover 11 and a keyboard base 35 at positions around the key caps 21. The key caps 21 are inserted in the insertion opening 71 and through the hole sections 15 of the upper cover 11, and are exposed to the outside of a casing 10.

In the portable computer 1 of the above structure, all key caps 21 are inserted in the single large insertion opening 71. With this structure, a keyboard unit 31 can be fabricated with ease.

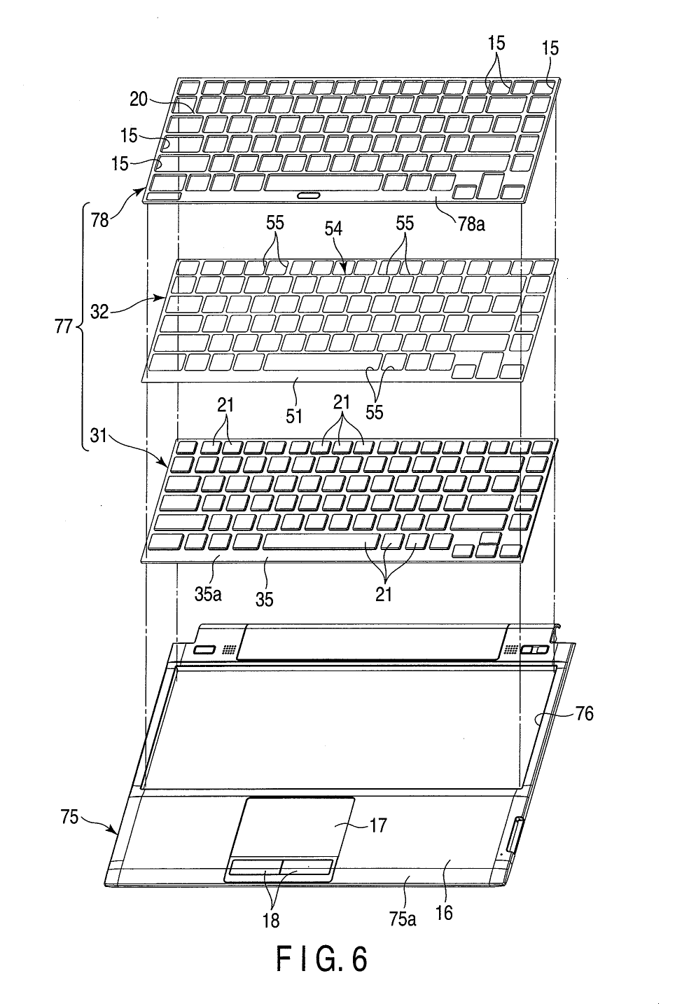

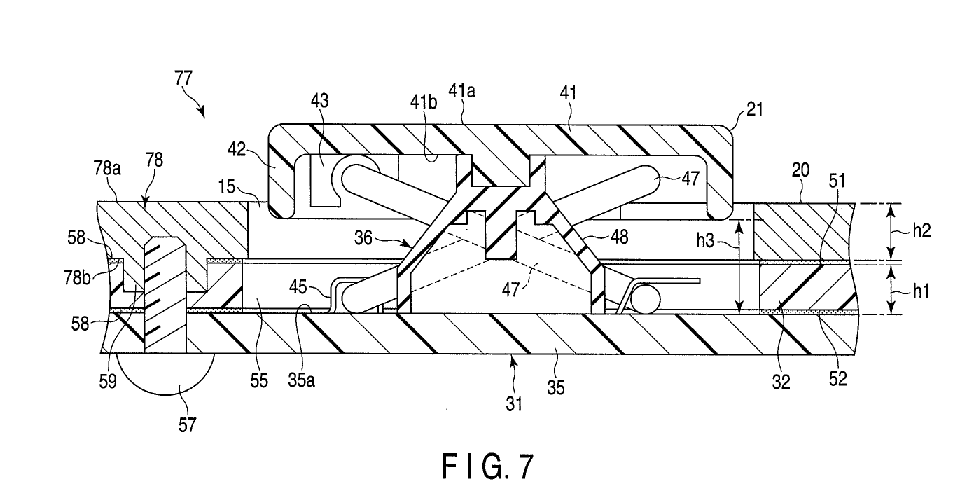

A description will now be given of a third embodiment with reference to FIGS. 6 and 7. In the description below, the same reference numerals will be used to denote structural elements having the same functions as the structural elements of the portable computer 1 of the first embodiment, and a repetitive description of such structural elements will be omitted.

FIG. 6 is a partly-exploded perspective view of the main unit 3 of a personal computer 1 according to the third embodiment. A casing 10 comprises a base cover 75 in place of the upper cover 11 described above. The base cover 75 is attached to a lower cover 12 in such a manner as to cover a lower cover 12.

As shown in FIG. 6, the base cover 75 has an upper face 75a. An opening section 76, a palm rest 16, a touch pad 17 and a pair of buttons 18 are provided on the upper face 75a of the base cover 75. The opening section 76 is located at the rear of the palm rest 16.

As shown in FIG. 6, a keyboard module 77 is fitted in the opening section 76. The keyboard module 77 comprises a cover member 78, a keyboard unit 31 and a spacer 32.

The cover member 78 is a flat plate formed of a magnesium alloy, for example. Needless to say, the cover member 78 may be formed of another kind of material, such as an aluminum alloy or a synthetic resin.

FIG. 7 is a sectional view showing part of the keyboard module 77. As shown in FIG. 7, the cover member 78 has a first face 78a and a second face 78b. The second face 78b is the opposite side of the first face 78a.

The cover member 78 comprises a plurality of hole sections 15. The hole sections 15 penetrate from the first face 78a of the cover member 78 to the second contact face 78b. Part of the key caps 21 are located in the respective hole sections 15. The key caps 21 are projected from the first face 78a of the cover member 78.

A spacer 32 is located between the cover member 78 and a keyboard base 35. The spacer 32 is secured to both the cover member 78 and the keyboard base 35 by use of fixing members 57 and an adhesive agent 58. In other words, the keyboard base 35 is attached to the second face 78b of the cover member 78, with the spacer 32 interposed.

The portable computer 1 of the above structure is advantageous in that the keyboard module 77 can be attached to the portable computer 1 by simply fitting the assembled keyboard module 77 in the opening section 76 of the base cover 75. Therefore, the portable computer 1 is easy to fabricate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the keyboard unit 31 is not limited to the pantograph type but may be a membrane type or another type. Further, the spacer 32 may be secured to the upper cover 11 and the keyboard base 35 by use of a double-sided adhesive tape.

In the above descriptions of the embodiments, reference was made to the portable computer 1 and to the keyboard module 77 employed with the portable computer 1. Needless to say, the present invention is applicable to other devices. For example, the present invention is applicable to a keyboard employed with a desktop computer.

What is claimed is:

1. A keyboard comprising:
a cover comprising a first face, a second face opposite to the first face and a plurality of holes through the cover from the first face to the second face;
a keyboard base attached to the second face of the cover;
a plurality of key caps supported by the keyboard base at positions corresponding to the holes and configured to move, the key caps being projected from the first face of the cover, at least a portion of the key caps being inside the holes; and
a spacer between the cover and the keyboard base and comprising a frame through which the key caps are configured to move.

2. The keyboard of claim 1, wherein the spacer comprises a material comprising a specific gravity less than that of the cover.

3. The keyboard of claim 2, wherein the frame comprises a plurality of frame holes corresponding to the holes configured to allow the key caps to move therethrough.

4. An electronic apparatus comprising:
a casing comprising a cover, the cover comprising a first face facing an outside region, a second face opposite to the first face and a plurality of holes through the cover from the first face to the second face;
a keyboard comprising
a keyboard base inside the casing, and
a plurality of key caps supported by the keyboard base corresponding to the holes, facing the outside region of the casing and configured to move; and
a spacer between the cover and the keyboard base and comprising a frame through which the key caps are configured to move,
wherein at least a portion of the key caps are being inside the holes.

5. The electronic apparatus of claim 4, wherein the spacer comprises a material comprising a specific gravity less than that of the cover.

6. The electronic apparatus of claim 5, wherein the frame comprises a plurality of frame holes corresponding to the holes configured to allow the key caps to move therethrough.

7. The electronic apparatus of claim 6, wherein the spacer is coupled to the cover the keyboard base by a waterproof adhesive agent.

8. The electronic apparatus of claim 6, wherein
the cove comprises a boss on the second face, and
the spacer and the keyboard are couple to the cover by an attaching member in the boss.

9. The electronic apparatus of claim 6, wherein the spacer comprises a first contact face coupled to the second face of the cover in plane contact with the second face, and a second contact face coupled to the keyboard base in plane contact with the keyboard base.

10. An electronic apparatus comprising:
a casing comprising a first face facing an outside region,
a second face opposite to the first face and a plurality of holes through the casing from the first face to the second face;
a keyboard comprising
a keyboard base arranged inside the casing, and
a plurality of key caps supported by the keyboard base corresponding to the holes, facing the outside region of the casing, and configured to move; and
a spacer between the casing and the keyboard base and comprising a frame through which the key caps are configured to move,
wherein at least a portion of the key caps are inside the holes.
